(19) United States
(12) Patent Application Publication
(10) Pub. No.: US 2026/0324499 A1
(43) Pub. Date: Oct. 15, 2026

(54) DENSE POWER SUPPLY ASSEMBLIES AND METHOD OF MAKING THEREOF

(71) Applicant: HRL Laboratories, LLC, Malibu, CA (US)

(72) Inventors: Greg BRACY, Malibu, CA (US); Avantika SODHI, Malibu, CA (US); John CARLSON, Malibu, CA (US)

(73) Assignee: HRL Laboratories, LLC, Malibu, CA (US)

(21) Appl. No.: 19/178,735

(22) Filed: Apr. 14, 2025

(51) Int. Cl. H01L 25/16; H01L 23/00; H01L 23/29; H01L 23/31; H01L 23/538

(52) U.S. Cl. CPC H10W 90/00; H10W 70/611; H10W 70/635; H10W 74/117; H10W 74/40; H10W 70/09; H10W 70/099; H10W 70/6528; H10W 90/22

(57) ABSTRACT

An electronic assembly, comprising a carrier wafer having a through-wafer cavities, wherein power component chips are held in the cavities by direct contact with an attachment metal that fills the cavities, such that control pads of the power component chips can be accessed from a bottom surface of the carrier wafer; and a substrate comprising through-substrate vias and control component chips attached to a bottom surface of the substrate such that contact pads of the control component chips are electrically connected to the vias; wherein a top surface of the substrate is attached to a bottom surface of the carrier wafer such that the vias are electrically connected to the contact pads of the power component chips.

### RELATED APPLICATIONS

This application relates to U.S. Pat. No. 10,998,273, entitled “Hybrid Integrated Circuit Architecture”, filed Oct. 11, 2018; which is hereby incorporated by reference in its entirety. This application relates to U.S. patent application Ser. No. 19/178,726 entitled “Integrated High Speed Module with large integrated inductors having embedded magnetic material”, filed concurrently with the present application, which is hereby incorporated by reference in its entirety.

### TECHNICAL FIELD

This presentation relates to integrated electronic modules or assemblies; in particular to hybrid assemblies comprising circuits made of different materials assembled together by electrometallurgy; in particular to assemblies provided to operate at high speed; in particular to power supply assemblies, in particular traction inverter assemblies.

### BACKGROUND

An electronic power supply assembly such as a traction inverter comprises at least a power transistor provided to swich strong currents at high speeds and a control circuit for controlling the switching of the power transistor. It generally also comprises a plurality of passive components such as capacitors and/or inductors, some of which being power components that will receive currents switched by at least one power transistor; and some of them being control components used by the control circuit.

It is known to use GaN transistors as power transistors in electronic power supply assemblies. GaN devices can operate at switching frequencies of several megahertz or even tens of megahertz making it 100 times faster than silicon devices. GaN has superior material properties such as high carrier mobility, low on-resistance, and low parasitic capacitance. In power electronics, high switching frequencies can reduce the size and weight of the components used in the circuit, while also improving efficiency.

Advances in interposer and 3D integration technologies enable the manufacture of ultra-compact multi-chip modules. Contemporary multi-chip power modules, such as traction inverters use discrete transistors and passive components integrated on ceramic or organic substrates using flip-chip or wire-bond interconnects. Popular traction inverters with discrete devices have gate drivers and voltage regulators designed in silicon and GaN transistors that are used as switches. For system cost considerations the number of GaN transistors is restricted to only those which are essential.

The reference entitled “Comprehensive Review and State of Development of Double-Sided Cooled Package Technology for Automotive Power Modules”, by M. Liu, A. Coppola, M. Alvi and M. Anwar, in in IEEE Open Journal of Power Electronics, vol. 3, pp. 271-289, 2022, doi: 10.1109/OJPEL.2022.3166684, which is hereby incorporated by reference in its entirety, discloses that power modules are core components of inverters in electric vehicles and their packaging technology has a critical impact on system performance and reliability. Conventional single sided cooled power modules have been one of the most common package structures for automotive applications. However, this design limits the performance of IGBT and future SiC power modules due to parasitic inductance and heat dissipation issues. Power module packaging technologies have been experiencing extensive changes as the performance expectations of the power semiconductor have increased. Over the past few decades, methods of double-sided cooling have attracted increased interest to enhance the power density of the inverter and effectively reduce its cost. This paper presents a comprehensive review of double-sided cooled packaging technology for automotive power modules. Technical details and innovative features of state-of-the-art automotive power modules from research institutes and major industry manufacturers are reviewed and their path into commercial vehicles is evaluated.

The reference, entitled “A Review of High-Speed GaN Power Modules: State of the Art, Challenges, and Solutions”, by A. I. Emon, Mustafeez-ul-Hassan, A. B. Mirza, J. Kaplun, S. S. Vala and F. Luo, in IEEE Journal of Emerging and Selected Topics in Power Electronics, vol. 11, no. 3, pp. 2707-2729, June 2023, doi: 10.1109/JESTPE.2022.3232265, which is hereby incorporated by reference in its entirety, discloses that Wide BandGap (WBG) devices are a desirable choice for high-density energy conversion systems. In high-speed hard-switching applications, voltage overshoot across device terminals, oscillations at gate loop, and electromagnetic interference (EMI) become harder to mitigate, and the overall system reliability is reduced. To address the key challenges and harness the benefits offered by these latest generations of devices, improved and advanced packaging structures are required, as packaging technology often has a critical impact on module performance and reliability. This article summarizes the design procedure for power modules, essential parts, and available materials for the fabrication of a power module package. Moreover, it provides a review of commercially available gallium nitride-based high electron mobility transistors (GaN HEMTs) and state-of-the-art module packaging technologies adopted for them with a focus on module layout, module integration trends, and identifying their impacts on the GaN HEMT's performance. Through this review, this article also discusses major challenges faced by designers with GaN HEMTs in power electronics applications and their potential solutions, which is critical for the mainstream adoption of GaN HEMTs and defining the future technology roadmap.

FIG. 1 illustrates the power density of traction inverters from various known electric vehicles and the highest power density they report is 60 kW/L. As detailed hereafter, these companies use a package stackup with double side cooling.

There exists a need for power supply assemblies that are more compact than the known ones, in particular traction inverters leading to higher power densities.

### SUMMARY

Embodiments of this presentation comprise a method of forming a compact scalable power supply unit with efficient thermal management

Other embodiments of this presentation comprise a method of packaging that embeds the power components of a power assembly in metal-filled cavities of a wafer, thus maximizing the removal of heat from the power components, wherein the control components of the power assembly are grouped on a HDI substrate a face of which is attached to a face of the wafer such that the control components are electrically connected to the power components. The method further comprises providing the other face of the wafer with a radiator structure. The method further comprises providing the other face of the substrate with bonding pins or balls.

Embodiments of this presentation comprise an electronic assembly thst includes a carrier wafer having a through-wafer cavities, wherein power component chips are held in the cavities by direct contact with an attachment metal that fills the cavities, such that control pads of the power component chips can be accessed from a bottom surface of the carrier wafer; and a substrate comprising through-substrate vias and control component chips attached to a bottom surface of the substrate such that contact pads of the control component chips are electrically connected to the vias; wherein a top surface of the substrate is attached to a bottom surface of the carrier wafer such that the vias are electrically connected to the contact pads of the power component chips.

Embodiments of this presentation include an electronic assembly, comprising: a carrier wafer having a top wafer surface and a bottom wafer surface; said carrier wafer comprising at least one through-wafer cavity having walls that join said top wafer surface to said bottom wafer surface; at least one power component chip having a power component chip top surface, a power component chip bottom surface and power component chip side surfaces, the power component chip being held in said at least one through-wafer cavity by direct contact of at least a side surface of said power component chip with an attachment metal that fills at least a portion of said at least one through-wafer cavity; the at least one power component chip comprising at least one power component chip contact pad on said power component chip bottom surface; and a substrate having a top substrate surface and a bottom substrate surface; said substrate comprising at least one through-substrate via that joins said top substrate surface to said bottom substrate surface; at least one control component chip having a control component chip top surface, a control component chip bottom surface and control component chip side surfaces, the at least one control component chip comprising at least one control component chip contact pad on said control component chip top surface; wherein the control component chip is attached to the bottom substrate surface such that the at least one control component chip contact pad is electrically connected to the at least one via; and wherein the top substrate surface is attached to the bottom wafer surface such that the at least one via is electrically connected to the at least one power component chip contact pad.

According to embodiments of this presentation, the at least one power component chip comprises a plurality of power component chips.

According to embodiments of this presentation, said at least one through-wafer cavity comprises a plurality of through-wafer cavities, wherein at least two of said plurality of power component chips are each held in a different one of said plurality of through-wafer cavities by direct contact with an attachment metal.

According to embodiments of this presentation, the plurality of power component chips comprises at least one of a power capacitor chip and a power inductor chip, and at least one power transistor chip.

According to embodiments of this presentation, said attachment metal covers the power component chip top surface as well as the top wafer surface.

According to embodiments of this presentation, said radiator structure is thermally coupled to a top surface of said attachment metal.

According to embodiments of this presentation, the at least one via is electrically connected to the at least one power component chip contact pad using at least one conductive pillar attached between the at least one power component chip contact pad and the at least one via.

According to embodiments of this presentation, the at least one control component chip comprises a plurality of control component chips, wherein some of said plurality of control component chips are electrically connected together using conductors arranged on the bottom substrate surface.

According to embodiments of this presentation, the plurality of control component chips are encapsulated in a thermal interface material.

According to embodiments of this presentation, the plurality of control component chips comprises at least one capacitor chip and at least one integrated circuit chip.

According to embodiments of this presentation, the at least one control component chip contact pad comprises a plurality of control component chip contact pads, wherein a first contact pad of said plurality of control component chip contact pads is electrically connected to the at least one via; and wherein wherein a second contact pad of said plurality of control component chip contact pads is electrically connected to a conductor arranged on the bottom substrate surface; said conductor being also electrically connected to a contact structure of the bottom substrate surface.

According to embodiments of this presentation, the contact structure of the bottom substrate surface comprises a bonding ball.

Other embodiments of this presentation include a method of manufacturing an electronic assembly; the method comprising: providing a carrier wafer having a top wafer surface and a bottom wafer surface, said carrier wafer comprising at least one through-wafer cavity having walls that join said top wafer surface to said bottom wafer surface; providing at least one power component chip having a power component chip top surface, a power component chip bottom surface and power component chip side surfaces, the at least one power component chip comprising at least one power component chip contact pad on said power component chip bottom surface; filling at least a portion of said at least one through-wafer cavity with an attachment metal so as to attach the power component chip in said at least one through-wafer cavity by direct contact of at least a side surface of said power component chip with said attachment metal; providing a substrate having a top substrate surface and a bottom substrate surface, said substrate comprising at least one through-substrate via that joins said top substrate surface to said bottom substrate surface; providing at least one control component chip having a control component chip top surface, a control component chip bottom surface and control component chip side surfaces, the at least one control component chip comprising at least one control component chip contact pad on said control component chip top surface; attaching the control component chip to the bottom substrate surface such that the at least one control component chip contact pad is electrically connected to the at least one via; and attaching the top substrate surface to the bottom wafer surface such that the at least one via is electrically connected to the at least one power component chip contact pad.

According to embodiments of this presentation, the at least one power component chip comprises a plurality of power component chips.

According to embodiments of this presentation, the at least one through-wafer cavity comprises a plurality of through-wafer cavities, the method comprising attaching at least two of said plurality of power component chips each in a different one of said plurality of through-wafer cavities by direct contact with an attachment metal.

According to embodiments of this presentation, the plurality of power component chips comprises at least one of a power capacitor chip and a power inductor chip, and at least one transistor chip.

According to embodiments of this presentation, said filling at least a portion of said at least one through-wafer cavity with an attachment metal comprises covering the power component chip top surface as well as the top wafer surface with said attachment metal.

According to embodiments of this presentation, the method further comprises providing a radiator structure and thermally coupling it to a top surface of said attachment metal.

According to embodiments of this presentation, the method further comprises attaching at least one conductive pillar between the at least one power component chip contact pad and the at least one via to connect electrically the at least one via to the at least one power component chip contact pad.

According to embodiments of this presentation, the at least one control component chip comprises a plurality of control component chips, the method further comprising electrically connecting at least some of said plurality of control component chips together using conductors arranged on the bottom substrate surface.

According to embodiments of this presentation, the plurality of control component chips comprises at least one capacitor chip and at least one transistor chip.

According to embodiments of this presentation, the method further comprises encapsulating the plurality of control component chips in a thermal interface material.

According to embodiments of this presentation, the at least one control component chip contact pad comprises a plurality of control component chip contact pads, the method comprising electrically connecting a first contact pad of said plurality of control component chip contact pads to the at least one via; and the method further comprising electrically connecting a second contact pad of said plurality of control component chip contact pads to a conductor arranged on the bottom substrate surface; said conductor being also electrically connected to a contact structure of the bottom substrate surface.

According to embodiments of this presentation, the contact structure of the bottom substrate surface comprises a bonding ball.

Other embodiments of this presentation include a method of manufacturing an electronic assembly, the method comprising: attaching a plurality of power component chips in through cavities of an interposer wafer by filling the cavities with an attachment metal, such that power contact pads of the power component chips are facing downward; exposing said power contact pads of the power component chips and forming conductive pillars in electrical contact with each of said power contact pads; providing a HDI substrate having traversing vias and attaching a top surface of said HDI substrate to a bottom surface of the interposer wafer such that said traversing vias are in electrical contact with the conductive pillars; attaching a plurality of control component chips having control contact pads to a bottom surface of the HDI substrate such that a first portion of said control contact pads are electrically connected to said traversing vias; and a second portion of said control contact pads is electrically connected to conducting lines on the bottom surface of the HDI substrate; and attaching ball grid array contact balls in electrical connection with said conducting lines on the bottom surface of the HDI substrate.

According to embodiments of this presentation, the method further comprises attaching a radiator structure to a top surface of the interposer wafer, such that said radiator structure is thermally coupled to said attachment metal.

### FIGURES

The above features will now be described in more details in relation with the following figures, wherein:

FIG. 1 illustrates the power density of traction inverters from various known electric vehicles.

FIG. 2 illustrates a cross section of an electronic assembly according to embodiments of this presentation.

FIG. 3A illustrates a known electronic assembly and its temperature mapping in operation.

FIG. 3B illustrates a combination of electronic assemblies according to embodiments of this presentation and its temperature mapping in operation.

FIG. 4 illustrates a method according to embodiments of this presentation.

FIGS. 5 to 9 illustrate each a cross section of a step of manufacturing an electronic assembly according to embodiments of this presentation.

FIG. 10 illustrates a method according to embodiments of this presentation.

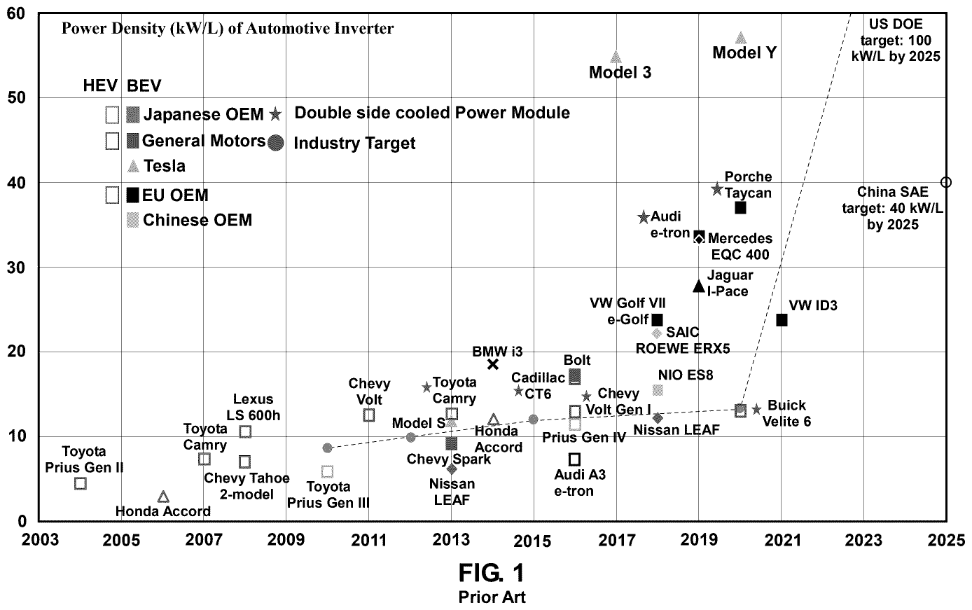

### DETAILED DESCRIPTION

The following description is presented to enable one of ordinary skill in the art to make and use the teachings of this presentation and to incorporate them in the context of particular applications. Various modifications, as well as a variety of uses in different applications will be readily apparent to those skilled in the art, and the general principles defined herein may be applied to a wide range of embodiments. Thus, the present invention is not intended to be limited to the embodiments presented, but is to be accorded the widest scope consistent with the principles and novel features disclosed herein.

In the following detailed description, numerous specific details are set forth in order to provide a more thorough understanding of embodiments of this presentation. However, it will be apparent to one skilled in the art that such embodiments may be practiced without necessarily being limited to these specilic details.

All the features disclosed in this presentatoin, (including any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

Furthermore, any element in a claim that does not explicitly state “means for” performing a specified function, or “step for” performing a specilic function, is not to be interpreted as a “means” or “step” clause as specified in 35 U.S.C. Section 112(f). In particular, the use of “step of′ or ”act of′ in the claims herein is not intended to invoke the provisions of 35 U.S.C. 112, Paragraph 6.

U.S. Pat. No. 10,998,273 teaches to integrate exotic components such as GaN transistors in a through-wafer cavity of a wafer having portions where an integrated circuit is formed. This presentation provides for using a similar process to attach the power components/chips of a power supply assembly by direct contact with an embedding/attachment metal in through-wafer cavities of a power wafer. The power wafer does not necessarily comprise portions where an integrated circuit is formed. Preferably, one side of each power component, bearing contact pads, is essentially flush with a bottom suface of the power wafer thus allowing to electrically connect the contact pads. Preferably, the other sides of each power component (i.e. five sides if the power component is a parallelepipedic chip) are in direct contact with the embedding/attachment metal. Preferably, the embedding/attachment metal also forms a layer that completely covers a top surface of the power wafer. A radiator structure can be thermally coupled to a top surface of said embedding/attachment metal layer. This arrangement advantageously allows evacuating any heat produced by the power components via five sides of the power components. Preferably, the control components, or components necessary to control the power components can be mounted on a bottom side of a High Density Interconnect (HDI) substrate, where conductive pillars are used to electrically connect the contact pads on the bottom of the power wafer to a top surface of the HDI substrate, and vias are used to electrically connect the conductive pillars to the control components on the bottom of the HDI substrate.

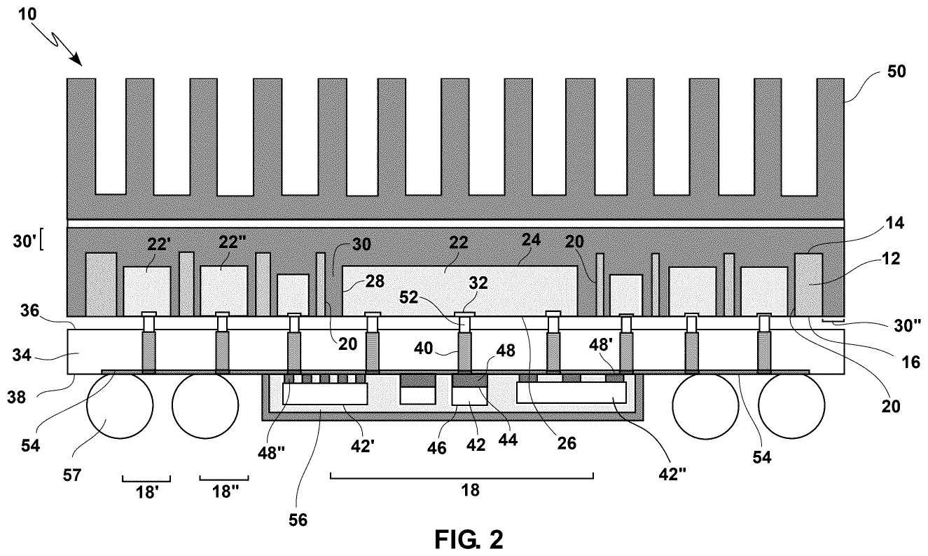

FIG. 2 illustrates a cross section of an electronic assembly 10 according to embodiments of this presentation, the assembly comprising a carrier wafer 12 (or power wafer) having a top wafer surface 14 and a bottom wafer surface 16 and comprising at least one through-wafer cavity 18 having walls 20 that join the top wafer surface 14 to the bottom wafer surface 16. According to embodiments of this presentation, at least one power component chip 22, having a power component chip top surface 24, a power component chip bottom surface 26 and power component chip side surfaces 28, is held in said at least one through-wafer cavity 18 by direct contact of at least a side surface 28 of power component chip 22 with an attachment metal 30 that fills at least a portion of the at least one through-wafer cavity 18. According to embodiments of this presentation, the at least one power component chip 22 comprises at least one power component chip contact pad 32 on the power component chip bottom surface 26.

According to embodiments of this presentation, assembly 10 further comprises a substrate 34, such as a High Density Interconnect (HDI) substrate, having a top substrate surface 36 and a bottom substrate surface 38, as well as at least one through-substrate via 40 that joins said top substrate surface 36 to said bottom substrate surface 38. At least one control component chip 42, having a control component chip top surface 44, a control component chip bottom surface 46, control component chip side surfaces, and at least one control component chip contact pad 48 on the control component chip top surface 44, having its top surface 44 attached to the bottom substrate surface 38 such that the at least one control component chip contact pad 48 is electrically connected to the at least one via 40. Further, the top substrate surface 36 is attached to the bottom wafer surface 16 such that the at least one via 40 is electrically connected to the at least one power component chip contact pad 32.

As illustrated, the at least one power component chip 22 can be a group of chips that comprises a plurality of power component chips such as the components marked with reference numbers 22′, 22″, and the at least one through-wafer cavity 18 can be a group of through-wafer cavities that comprises a plurality of through-wafer cavities, such as the cavities marked with reference numbers 18′, 18″, wherein at least two of said plurality of power component chips 22, 22′, 22″ are each held in a different one of said plurality of through-wafer cavities 18,18′, 18″ by direct contact with an attachment metal. In some embodiments (not illustrated), two power components chips can also be held in a single through wafer cavity. According to embodiments of this presentation, the plurality of power component chips 22, 22′, 22″ comprises at least one of a power transistor such as a GaN transistor, a power capacitor chip, a power inductor chip. According to embodimens of this presentation, a component is a “power” component if it is provided for handling power densities >⁵⁰ W/cm³. For some high power applications power supplies must be capable of delivering power in the range of 300 W->2 KW, some server applications require power>2 KW and some AI boards require power upto 1 KW. Very high power applications can require power >50 KW like power train used in automotives. It is to be noted that even components that are not provided for operating in such power ranges can be integrated together with the power components in cavities 18, 18′, 18″ . . . of wafer 12. This is true in particular for bulky components such as large capacitors or large inductors that would be cumbersome to attach to the bottom of substrate 34. According to embodiments of this presentation, bulky components can be components having a thickness larger than 300 micrometer, and they can have a thickness of 550 or 600 micrometer. According to embodiments of this presentation, wafer 12 has a thickness in the range of 50um to 1 mm. Wafer 12 can be a silicon wafer or it can be made of another material such as glass or SIC wafer also.

. As Illustrated in FIG. 2, the attachment metal 30 that embeds the power components 22, 22′, 22″, . . . in the cavities 18, 18′, 18″ of wafer 12 can also form a metal layer 30′ that covers a portion, or all, of the top surface 14 of the wafer 12, in addition to the top surfaces of all the power components 22, 22′, 22″. As Illustrated in FIG. 2, the attachment metal 30 can also form a metal layer 30″ that covers a portion, or all, of the sides of the wafer 12. These layers of metal 30′, 30″ can help evacuate heat produced by the power components 22, 22′, 22″ and captured by the metal 30 that embeds the power components 22. 22′, 22″ in the cavities 18, 18′, 18″. According to embodiments of this presentation, a radiator structure 50 can be thermally coupled to a top surface of the attachment metal layer 30′. The radiator can be welded or attached in another manner (e.g. bolted or clipped) with a heat conductive material between the radiator and the top surface of the attachment metal.

As also illustrated in FIG. 2, the at least one via 40 can be electrically connected to the at least one power component chip contact pad 32 using at least one conductive pillar 52 attached between the at least one power component chip contact pad 32 and the at least one via 40. According to embodiments of this presentation, the at least one control component chip 42 comprises a plurality of control component chips 42′, 42″, etc . . . , wherein some of said plurality of control component chips 42, 42′, 42″, etc . . . are electrically connected together using conductors 54 arranged on the bottom substrate surface 38. According to embodiments of this presentation, the plurality of control component chips 42, 42′, 42″, etc . . . comprises at least one capacitor chip and at least one integrated circuit, for example a silicon integrated circuit such as a gate driver or a linear regulator.

According to embodiments of this presentation, the plurality of power components 22, 22′, 22″ have a plurality of contract pads 32 and one conductive pillar 52 is formed in contact with each contact pad 32, for example by electrometallurgy using a temporary mask formed on the bottom surface 16 of the wafer 12. The conductive pillars 52 can form an array of pillars a bottom end of which can be press-bonded in contact with a top end of the vias 40 in substrate 34. The pillar array allows attaching the wafer 12 to the substrate 34 such that the control components 42 are electrically connected to the appropriate power components 22, while minimizing heat transfer from the power wafer to the control components 42.

According to embodiments of this presentation, the plurality of control component chips 42, 42′, 42″, etc . . . are encapsulated in a thermally conducting mold compound material 56 to ease taking out heat from the control components. According to embodiments of this presentation, the at least one control component chip contact pad 48 comprises a plurality of control component chip contact pads 48, 48′, 48″, etc . . . , wherein a first contact pad 48 of said plurality of control component chip contact pads 48, 48′, 48″, etc .. . . , is electrically connected to the at least one via 40; and wherein wherein a second contact pad 48′ of said plurality of control component chip contact pads 48, 48′, 48″, etc . . . , is electrically connected to a conductor 54 arranged on the bottom substrate surface 38; said conductor 54 being also electrically connected to a contact structure 57 of the bottom substrate surface 38. According to embodiments of this presentation, contact structure 57 can be a bonding ball so as to form a Ball Grid Array on the bottom substrate surface 38. Contact structure can also be a welding pin (not illustrated). According to embodiments of this presentation, all the control components have a height that, once assembled to the bottom substrate surface 38 and encapsulated in a thermal interface material 56, is still below a standoff height of the BGA formed by contact structures 57 after reflow. Such a structure allows assembling a plurality of assemblies 10 on a single PCB in a scalable manner, as illustrated hereafter.

Because embodiments of this presentation allow integrating GaN power transistors with silicon drivers and regulators in a compact foot-print, they allow providing a self-sufficient power supply unit that has 2 fold advantages: a high output power density due to the use of GaN power transistors and a silicon compatible drive input. The combined unit can look like a silicon circuit at the input and is capable of providing high density power conversion systems using GaN transistors. The metal-embedding of one or more GaN power transistors and other power components in cavities of a same wafer allow efficient heat removal, such that the temperature rise propagated to the control circuit is within acceptable limits for silicon to function in a desired manner. GaN transistors can operate at temperatures >125 DegC and maximum operating junction temperature for silicon chips must be <85 DegC for reliable operation. Since GaN can operate at higher temperatures it can afford to dissipate more power. Thus, for a given device efficiency a GaN based power supply can output more power. As for example shown in the reference “Gallium Nitride vs Silicon in Soft Switching LLC Power Supplies Comparative Study”, by J. Jirsa and O. Tudor-Stroe (https: //passive-components.eu/gallium-nitride-vs-silicon-in-soft-switching-llc-power-supplies- comparative-study/), to get a comparable performance between Si and GaN the GaN device operates at 54.3 degC and the Si device operates at 111 degC. As heat from the GaN transistor is efficiently extracted from 5 out of 6 facets of the power components according to embodiments of this presentation, the thermal front propagation is well controlled and allows for placement of a silicon IC in close proximity of the GaN power transistor. Thus, embodiments of this presentation allow achieving size reduction in a packaged sub-system, thereby increasing the power density delivered by a packaged unit of a given size. This result is beneficial in for example the domain of electrical vehicles as it allows packing ultra-high density efficient power supplies in a very compact foot-print so that the range of travel for a given battery charge of an electric vehicle can be extended. This also saves on the energy required for the cooling electronics of an electric vehicle. The compactness of a power supply built using these units could also be beneficial to space borne applications.

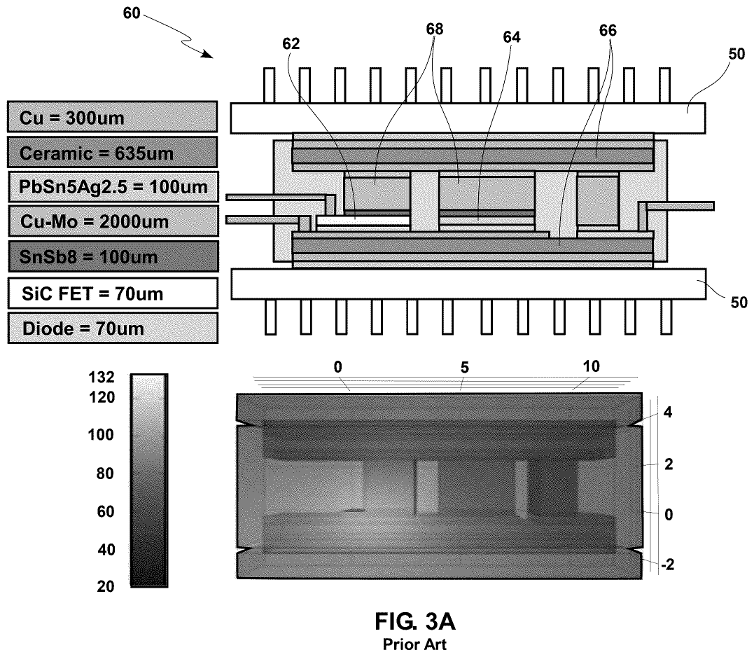

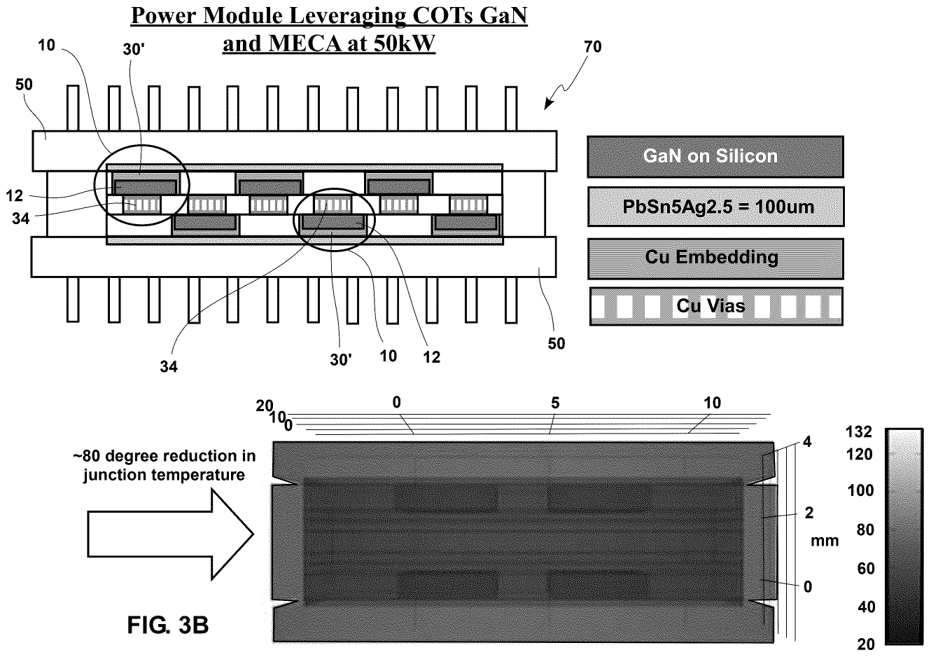

FIG. 3A illustrates a known electronic assembly 60 comprising a 50 KW power transistor 62 and a power diode 64 connected to a pair of control substrates 66 using various layers of copper and welding, as well as Cu/Mo columns 68. The control substrates have exterior surfaces thermally coupled to radiator structures 50. FIG. 3A also shows the temperature mapping of assembly 60 in operation, where a temperature of 132 Celsius is reached by the transistor. The ceramic/control substrates can be like PCBs but in ceramics; the top substrate can route top electrodes to Cu/Mo columns that connect those pads to a bottom ceramic substrate so they can be connected to external circuits by Cu bus-bars attached to the bottom ceramic substrate.

FIG. 3B illustrates a module 70 comprising a combination of a plurality of electronic assemblies 10 according to embodiments of this presentation, arranged alternatively upside-up and upside down such that one assembly 10 out of two has the metal layer 30′ on the outside surface of its wafer 12 thermally coupled/attached to a first, top, radiator 50 and such that the other assembly 10 out of two has the metal layer 30′ on the outside surface of its wafer 12 thermally coupled/attached to a second, bottom, radiator 50. A heat conducting dielectric can be used to atttach all the assemblies 10 together to form module 70. From above, the module 70 can present a checkered pattern, with each row and column of the pattern having one assembly 10 out of two facing upward. The inventors have shown that such a combination of assemblies according to embodiments of this presentation allows using a plurality of power transistors having a combined power of 50 KW, where the temperature in operation of the combination does not go above 52 degrees Celsius. A comparison of the thermal performance of the state of the art in FIG. 3A with the proposed design of FIG. 3B shows a 1.5× improvement in the thermal resistance to a cooling fluid. Preferably, an interposer substrate can be sandwiched between the top and bottom devices, the interposer substrate being provided to route the inout-output connections to the outside world and connect I/O pads of the GaN devices. GaN devices used here have I/O pads on a same side of the device unlike the vertical FETs used in FIG. 3A. Importantly, the metal embedding of a plurality of devices according to embodiments of this presentation evens out any device height variations such that a cooling solution can be effective mounted to multiple devices in one step.

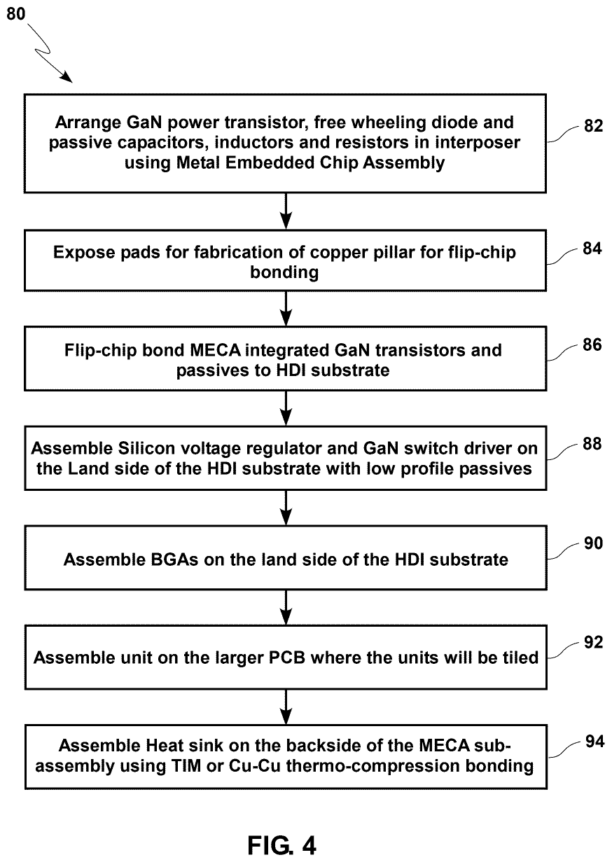

.FIG. 4 illustrates a method 80 according to embodiments of this presentation, the method comprising a method of manufacturing an electronic assembly, the method comprising: arranging and attaching 82 a plurality of power component chips in through cavities of an interposer wafer by filling the cavities with an attachment metal, such that power contact pads of the power component chips are facing downward when the wafer is flipped; exposing 84 said power contact pads of the power component chips and forming conductive pillars in electrical contact with each of said power contact pads; providing 86 a HDI substrate having traversing vias and attaching a top surface of said HDI substrate to a bottom surface of the (flipped) interposer wafer such that said traversing vias are in electrical contact with the conductive pillars; assembling 88 a plurality of control component chips such as silicon voltage regulators and GaN swith drivers on the land side (bottom surface) of the HDI substrate. Low profile passive components can also be part of these chips. The above step can include assembling a plurality of control component chips having control contact pads to a bottom surface of the HDI substrate such that a first portion of said control contact pads are electrically connected to said traversing vias; and a second portion of said control contact pads is electrically connected to conducting lines on the bottom surface of the HDI substrate to connect the components together; and attaching 90 ball grid array contact balls in electrical connection with said conducting lines on the bottom surface of the HDI substrate. Optionally, the method comprises attaching 92 the assembly to a larger PCB where a plurality of assemblies can be tiled/assembled in an array such as described in relation with FIG. 3B. Optionally, method 80 further comprises 94 attaching radiator structures to the top surfaces of the interposer wafers, such that the radiator structures are thermally coupled to the attachment metal.

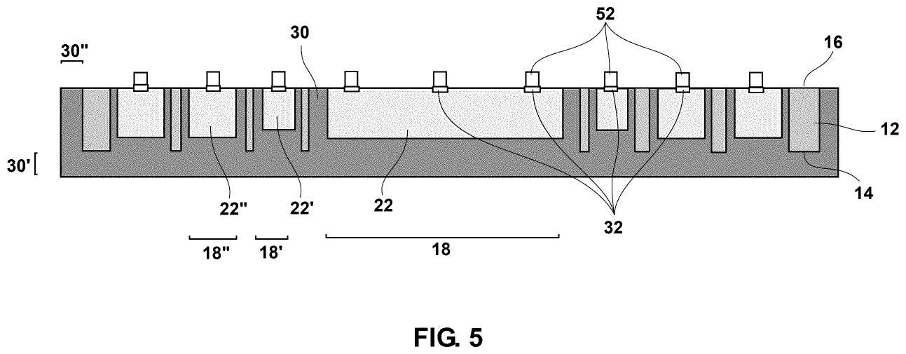

FIGS. 5 to 9 illustrate each a cross section of a step of manufacturing an electronic assembly according to embodiments of this presentation.

FIG. 5 shows a cross section of a carrier wafer 12 having a top (when flipped) wafer surface 14 and a bottom (when flipped) wafer surface 16 and comprising a plurality of through-wafer cavities 18, 18′, 18″ joining the top wafer surface 14 to the bottom wafer surface 16. A plurality of power component chips 22, 22′, 22″, etc . . . , having each at least one contact pad 32 are held in the through-wafer cavities 18, 18′, 18″ by direct contact with an attachment metal 30 that fills at least a portion of each of the through-wafer cavities 18, 18′, 18″. The power component chips 22, 22′, 22″ are arranged in the wafer such that contact pads 32 can be accessed on the side of the bottom surface 16 of the wafer (bottom when the wafer is flipped). The power component chips 22, 22′, 22″, which can comprise bulky components in addition to components provided for handling power, are attached into the cavities of wafer 12 using for example the technology detailed in U.S. Pat. No. 10,998,273, which is hereby incorporated by reference in its entirety.

As illustrated, copper pillars 52 can be formed, for example using masks and elecrometallurgy, to contact each contact pad 32 of the power component chips 22, 22′, 22″, and form a pillar grid array. Optionally, a layer of heat conductive dielectric (not shown) can be used to cover the face 16 of the wafer 12 such that only distal ends of the pillars 52 protrude from the dielectric. As Illustrated in FIG. 2, the attachment metal 30 that embeds the power components 22, 22′, 22″, . . . in the cavities 18, 18′, 18″ of wafer 12 can also form a metal layer 30′ that covers a portion, or all, of the top surface 14 of the wafer 12, in addition to the top surfaces of all the power components 22, 22′, 22″. As Illustrated the attachment metal 30 can also form a metal layer 30″ that covers a portion, or all, of the sides of the wafer 12.

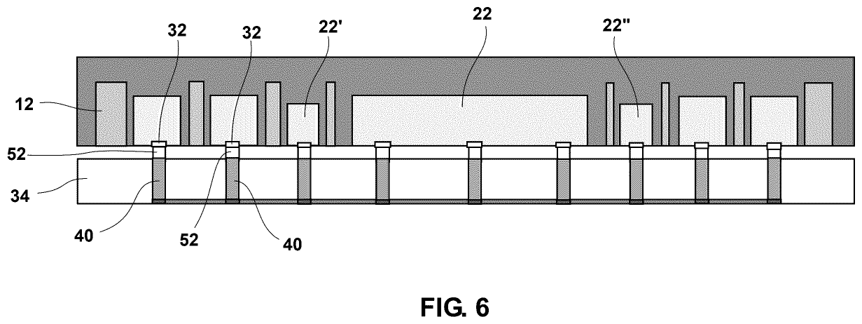

FIG. 6 illustrates the wafer 12 of FIG. 6 after it was flipped and attached to a top surface of a substrate 34, for example a High Density Interconnect (HDI) substrate, that is traversed by vias 40, such that a distal (bottom when flipped) end of each pillar 52 is in electrical contact with a top end of a via 40. The HDI substrate can for example be attached to the wafer with embedded chips using copper pillars with solder caps using flip chip assembly methods.

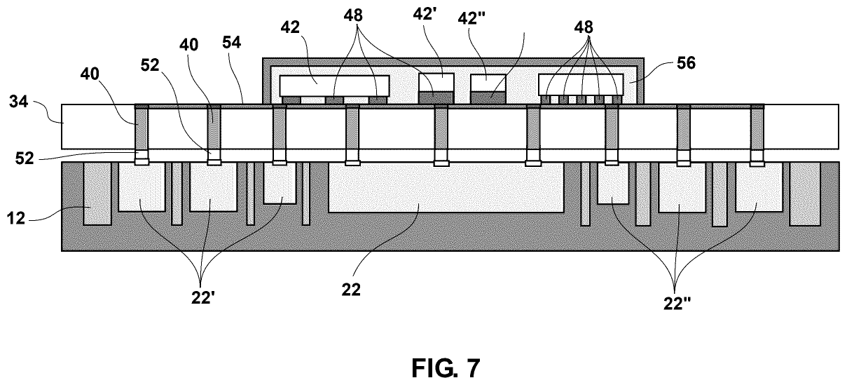

FIG. 7 illustrates the assembly of FIG. 6 of wafer 12 and substrate 34 after a plurality of control component chips 42, 42′, 42″, etc . . . having each at least one control component chip contact pad 48 are attached to the bottom (when flipped) surface of substrate 34 such that the contact pads 48 are connected to the vias 40, eventually using conducting lines 54 formed on the bottom (when flipped) surface of substrate 34, in a manner that allows the control component chips 42, 42′, 42″, etc . . . to exchange control signals with the power components 22, 22′, 22″ in wafer 12. As illustrated, the plurality of control component chips 42, 42′, 42″ etc . . . are encapsulated in a thermal interface material 56 to ease taking out heat from the control components.

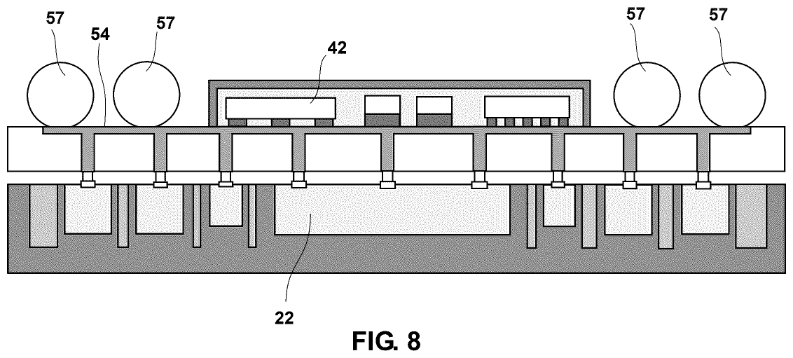

FIG. 8 illustrates the assembly of FIG. 7 after conducting lines 54 are also electrically connected to a contact balls 57, thus forming on the bottom (when flipped) surface of substrate 34 a ball grid array allowing to communicate with/control the control circuits 42, etc . . . and connected power circuits 22, etc . . .

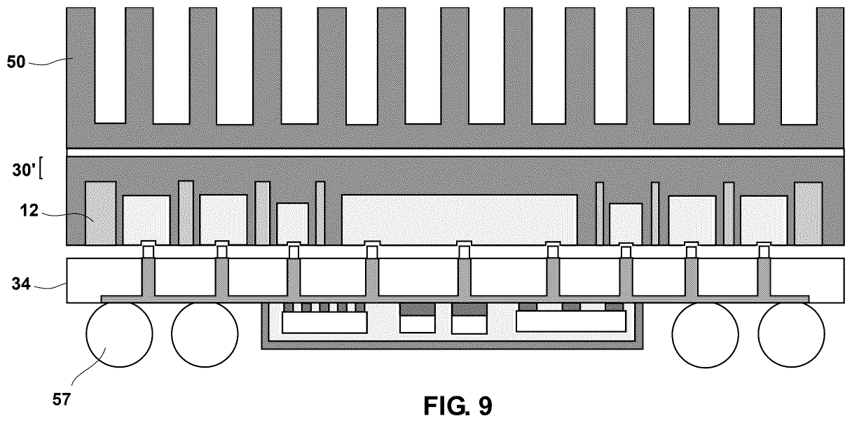

FIG. 9 illustrates the assembly of FIG. 8 after it was flipped and a radiator structure 50 was attached and thermally coupled to the top surface of the attachment metal layer 30′.

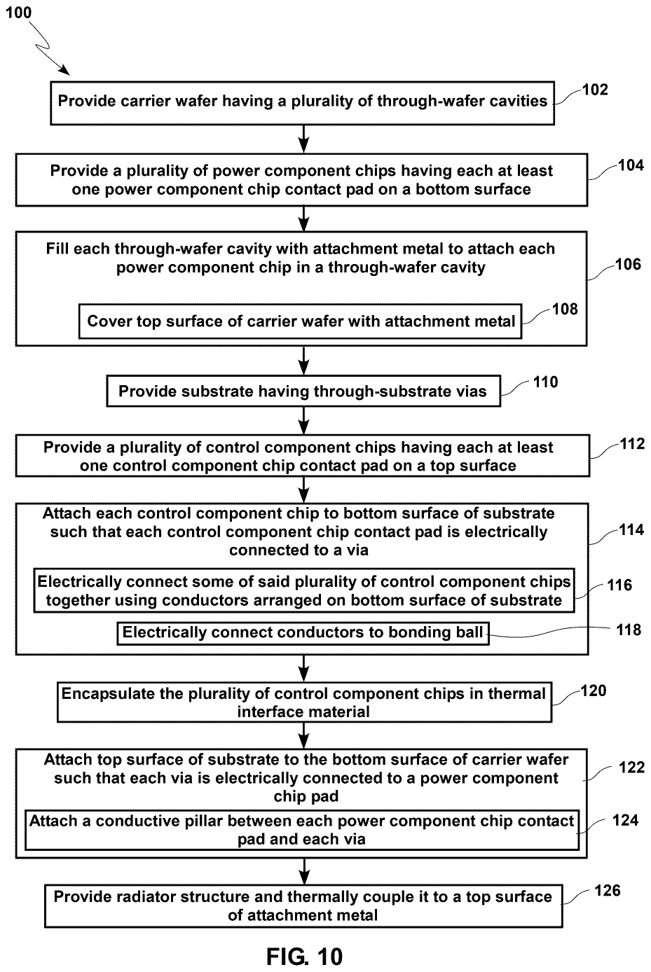

FIG. 10 illustrates a method 100 according to embodiments of this presentation, the method comprising providing 102 a carrier wafer having a top wafer surface and a bottom wafer surface, the carrier wafer comprising at least one through-wafer cavity having walls that join the top wafer surface to the bottom wafer surface; providing 104 at least one power component chip having a power component chip top surface, a power component chip bottom surface and power component chip side surfaces, the at least one power component chip comprising at least one power component chip contact pad on the power component chip bottom surface; and filling 106 at least a portion of the at least one through-wafer cavity with an attachment metal so as to attach the power component chip in the at least one through-wafer cavity by direct contact of at least a side surface of the power component chip with the attachment metal. Optionally, the filling 106 of the at least one through-wafer cavity with metal can comprise covering 108 the power component chip top surface as well as the top wafer surface with the attachment metal.

According to embodiments of this presentation, Method 100 further comprises providing 110 a substrate having a top substrate surface and a bottom substrate surface, the substrate comprising at least one through-substrate via that joins the top substrate surface to the bottom substrate surface; providing 112 at least one control component chip having a control component chip top surface, a control component chip bottom surface and control component chip side surfaces, the at least one control component chip comprising at least one control component chip contact pad on the control component chip top surface; and attaching 114 the control component chip to the bottom substrate surface such that the at least one control component chip contact pad is electrically connected to the at least one via. According to embodiments of this presentation, the at least one control component chip comprises a plurality of control component chips, and the method further comprises electrically connecting 116 at least some of the plurality of control component chips together using conductors arranged on the bottom substrate surface. The method can also comprise attaching and electrically connecting 118 bonding balls to the conductors. The method can also comprise encapsulating 120 the plurality of control component chips in a thermal interface material.

According to embodiments of this presentation, the method further comprises attaching 122 the top substrate surface to the bottom wafer surface such that the at least one via is electrically connected to the at least one power component chip contact pad. The attaching 122 can include attaching 124 a one conductive pillar between the at least one power component chip contact pad and the at least one via to connect electrically the at least one via to the at least one power component chip contact pad.

The method can also comprise providing 126 a radiator structure and thermally coupling it to a top surface of said attachment metal.

In summary, embodiments of this presentation improve upon the existing stacking processes by embedding GaN transistors in a larger silicon wafer using copper. Thereby providing 5 surfaces for heat conduction as opposed to one or two surfaces, in prior art, to which the CuMo spacers are mounted. Further, some prior art relies on thinning SiC wafers to make dominant conduction paths to be on top and bottom. However, such a thinning process makes IC handing very challenging. Also it introduces height variation from IC to passives for which spacers have to be mounted to equalize the height of all components in e.g. a half-bridge circuit. This presentation provides for embedding thick ICs in the silicon wafer, thereby avoiding the need to thin the IC and utilizing all the 6 facets for heat conduction. In addition, using the metal embedding process detailed above also allows embedding passives in the silicon wafer, thus allowing to even out height disparities in a single process and making assembly much more streamlined and cost-effective.

The foregoing Detailed Description of exemplary and preferred embodiments is presented for purposes of illustration and disclosure in accordance with the requirements of the law. It is not intended to be exhaustive nor to limit the invention to the precise form(s) described, but only to enable others skilled in the art to understand how the invention may be suited for a particular use or implementation. The possibility of modifications and variations will be apparent to practitioners skilled in the art. No limitation is intended by the description of exemplary embodiments which may have included tolerances, feature dimensions, specific operating conditions, engineering specifications, or the like, and which may vary between implementations or with changes to the state of the art, and no limitation should be implied therefrom.

Applicant has made this disclosure with respect to the current state of the art, but also contemplates advancements and that adaptations in the future may take into consideration of those advancements, namely in accordance with the then current state of the art. It is intended that the scope of the invention be defined by the Claims as written and equivalents as applicable. Reference to a claim element in the singular is not intended to mean “one and only one” unless explicitly so stated. Moreover, no element, component, nor method or process step in this disclosure is intended to be dedicated to the public regardless of whether the element, component, or step is explicitly recited in the Claims. No claim element herein is to be construed under the provisions of 35 U.S.C. Sec. 112(f), sixth paragraph, unless the element is expressly recited using the phrase “means for . . . ” and no method or process step herein is to be construed under those provisions unless the step, or steps, are expressly recited using the phrase “comprising the step(s) of . . . ”

All elements, parts and steps described herein are preferably included. It is to be understood that any of these elements, parts and steps may be replaced by other elements, parts and steps or deleted altogether as will be obvious to those skilled in the art.

1. An electronic assembly, comprising:
a carrier wafer having a top wafer surface and a bottom wafer surface;
said carrier wafer comprising at least one through-wafer cavity having walls that join said top wafer surface to said bottom wafer surface;
at least one power component chip having a power component chip top surface, a power component chip bottom surface and power component chip side surfaces, the power component chip being held in said at least one through-wafer cavity by direct contact of at least a side surface of said power component chip with an attachment metal that fills at least a portion of said at least one through-wafer cavity;
the at least one power component chip comprising at least one power component chip contact pad on said power component chip bottom surface; and
a substrate having a top substrate surface and a bottom substrate surface;
said substrate comprising at least one through-substrate via that joins said top substrate surface to said bottom substrate surface;
at least one control component chip having a control component chip top surface, a control component chip bottom surface and control component chip side surfaces, the at least one control component chip comprising at least one control component chip contact pad on said control component chip top surface; wherein
the control component chip is attached to the bottom substrate surface such that the at least one control component chip contact pad is electrically connected to the at least one via; and wherein the top substrate surface is attached to the bottom wafer surface such that the at least one via is electrically connected to the at least one power component chip contact pad.

2. The electronic assembly of claim 1, wherein the at least one power component chip comprises a plurality of power component chips.

3. The electronic assembly of claim 2, wherein said at least one through-wafer cavity comprises a plurality of through-wafer cavities, wherein at least two of said plurality of power component chips are each held in a different one of said plurality of through-wafer cavities by direct contact with an attachment metal.

4. The electronic assembly of claim 1, wherein said attachment metal covers the power component chip top surface as well as the top wafer surface.

5. The electronic assembly of claim 4, wherein said a radiator structure is thermally coupled to a top surface of said attachment metal.

6. The electronic assembly of claim 1, wherein the at least one via is electrically connected to the at least one power component chip contact pad using at least one conductive pillar attached between the at least one power component chip contact pad and the at least one via.

7. The electronic assembly of claim 1, wherein the at least one control component chip comprises a plurality of control component chips, wherein some of said plurality of control component chips are electrically connected together using conductors arranged on the bottom substrate surface.

8. The electronic assembly of claim 7, wherein the plurality of control component chips are encapsulated in a thermal interface material.

9. The electronic assembly of claim 1, wherein the at least one control component chip contact pad comprises a plurality of control component chip contact pads, wherein a first contact pad of said plurality of control component chip contact pads is electrically connected to the at least one via; and wherein wherein a second contact pad of said plurality of control component chip contact pads is electrically connected to a conductor arranged on the bottom substrate surface; said conductor being also electrically connected to a contact structure of the bottom substrate surface.

10. The electronic assembly of claim 9, wherein the contact structure of the bottom substrate surface comprises a bonding ball.

11. A method of manufacturing an electronic assembly; the method comprising:
providing a carrier wafer having a top wafer surface and a bottom wafer surface, said carrier wafer comprising at least one through-wafer cavity having walls that join said top wafer surface to said bottom wafer surface;
providing at least one power component chip having a power component chip top surface, a power component chip bottom surface and power component chip side surfaces, the at least one power component chip comprising at least one power component chip contact pad on said power component chip bottom surface;
filling at least a portion of said at least one through-wafer cavity with an attachment metal so as to attach the power component chip in said at least one through-wafer cavity by direct contact of at least a side surface of said power component chip with said attachment metal;
providing a substrate having a top substrate surface and a bottom substrate surface, said substrate comprising at least one through-substrate via that joins said top substrate surface to said bottom substrate surface;
providing at least one control component chip having a control component chip top surface, a control component chip bottom surface and control component chip side surfaces, the at least one control component chip comprising at least one control component chip contact pad on said control component chip top surface;
attaching the control component chip to the bottom substrate surface such that the at least one control component chip contact pad is electrically connected to the at least one via; and
attaching the top substrate surface to the bottom wafer surface such that the at least one via is electrically connected to the at least one power component chip contact pad.

12. The method of claim 11, wherein the at least one power component chip comprises a plurality of power component chips.

13. The method of claim 12, wherein said at least one through-wafer cavity comprises a plurality of through-wafer cavities, the method comprising attaching at least two of said plurality of power component chips each in a different one of said plurality of through-wafer cavities by direct contact with an attachment metal.

14. The method of 11, wherein said filling at least a portion of said at least one through-wafer cavity with an attachment metal comprises covering the power component chip top surface as well as the top wafer surface with said attachment metal.

15. The method of claim 14, comprising providing a radiator structure and thermally coupling it to a top surface of said attachment metal.

16. The method of claim 11, comprising attaching at least one conductive pillar between the at least one power component chip contact pad and the at least one via to connect electrically the at least one via to the at least one power component chip contact pad.

17. The method of claim 11, wherein the at least one control component chip comprises a plurality of control component chips, the method further comprising electrically connecting at least some of said plurality of control component chips together using conductors arranged on the bottom substrate surface.

18. The method of claim 17, further comprising encapsulating the plurality of control component chips in a thermal interface material.

19. The method of 11, wherein the at least one control component chip contact pad comprises a plurality of control component chip contact pads, the method comprising electrically connecting a first contact pad of said plurality of control component chip contact pads to the at least one via; and the method further comprising electrically connecting a second contact pad of said plurality of control component chip contact pads to a conductor arranged on the bottom substrate surface; said conductor being also electrically connected to a contact structure of the bottom substrate surface.

20. A method of manufacturing an electronic assembly, the method comprising:
attaching a plurality of power component chips in through cavities of an interposer wafer by filling the cavities with an attachment metal, such that power contact pads of the power component chips are facing downward;
exposing said power contact pads of the power component chips and forming conductive pillars in electrical contact with each of said power contact pads;
providing a HDI substrate having traversing vias and attaching a top surface of said HDI substrate to a bottom surface of the interposer wafer such that said traversing vias are in electrical contact with the conductive pillars;
attaching a plurality of control component chips having control contact pads to a bottom surface of the HDI substrate such that a first portion of said control contact pads are electrically connected to said traversing vias; and a second portion of said control contact pads is electrically connected to conducting lines on the bottom surface of the HDI substrate; and attaching ball grid array contact balls in electrical connection with said conducting lines on the bottom surface of the HDI substrate.
